(19) United States
(12) Patent Application Publication
(10) Pub. No.: US 2006/0214679 A1
(43) Pub. Date: Sep. 28, 2006

(54) Active diagnostic interface for wafer probe applications

(75) Inventors: Roy J. Henson, Pleasanton, CA (US); Matthew E. Chraft, Copperopolis, CA (US)

Correspondence Address: FLIESLER MEYER, LLP, FOUR EMBARCADERO CENTER, SUITE 400, SAN FRANCISCO, CA, 94111, US

(73) Assignee: FormFactor, Inc., Livermore, CA (US)

(21) Appl. No.: 11/091,069

(22) Filed: Mar. 28, 2005

(51) Int. Cl. G01R 31/26

(52) U.S. Cl. 324/765

(57) ABSTRACT

A diagnostic interface on a wafer probe card is provided to enable monitoring of test signals provided between the test system controller and one or more DUTs on a wafer during wafer testing. To prevent distortion of test signals on the channel lines, in one embodiment buffers are provided on the probe card as part of the diagnostic interface connecting to the channels. In another embodiment, an interface adapter pod is provided that connects to the diagnostic interface on the probe card to process the test results and provide the results to a user interface such as a personal computer.

### BACKGROUND

1. Technical Field

The present invention relates to an interface for monitoring test signals provided to and from a probe card used for contacting and testing devices under test (DUTs) on a wafer.

2. Related Art

Test systems for testing DUTs on wafers during manufacture typically include an Automatic Test Equipment (ATE) tester or test system controller, and a probe card for connecting channels from the test system controller to DUTs on a wafer. A conventional test system is shown in FIG. 1, and described in more detail subsequently.

The ATE test system controller is a significant cost factor in a test system, and includes equipment to generate test signals on channels to provide to contact pads on multiple DUTs. The test system controller further receives and analyzes responses from the DUTs. Test results for all DUTs on a wafer are displayed by the test system controller on a user interface.

The probe cards that carry signals between the test system controller and DUTs on a wafer are much less expensive than the test system controllers. Different probe cards are, thus, used to connect a single test system controller to many possible DUT pin configurations on a wafer to eliminate the expense of purchasing a new test system controller for each configuration of DUTs on a wafer. Probe cards, serving as an interface between a test system controller and a wafer, are typically much less expensive than a test system controller, and typically replaced after a much shorter lifecycle than the test system controller due to wear of probes on the probe card.

Wafer test systems are typically used in one instance to test memory components, such as dynamic random access memory (DRAM) on a wafer during manufacture before the wafer is diced up into individual chips. For DRAM redundant rows of memory devices can be created, and the test system is used to identify rows with failed memory cells or locations. In one manufacturing method, rows of DUTs with faulty cells are disconnected before manufacture is completed. In another process, after testing, additional manufacturing steps may be performed to correct defects in particular cells before manufacturing is completed.

FIG. 1 shows a block diagram of a test system using a probe card for testing DUTs on a semiconductor wafer. The test system includes a test system controller 4, which may be an ATE tester or general purpose computer, connected by a communication cable 6 to a test head 8. The test system further includes a prober 10 made up of a stage 12 for mounting a wafer 14 being tested, the stage 12 being movable to contact the wafer 14 with probes 16 on a probe card 18. The prober 10 includes the probe card 18 supporting probes 16 which contact DUTs formed on the wafer 14.

In the test system, test signals are generated by the test system controller 4 and transmitted through the communication cable 6, test head 8, probe card 18, probes 16 and ultimately to DUTs on the wafer 14. Test data provided from the test system controller 4 is divided into the individual test channels provided through the cable 6 and separated in the test head 8 so that each channel is carried to a separate one of the probes 16. The channels from the test head 8 are linked by connectors 24 to the probe card 18. The probe card 18 then links each channel to a separate one of the probes 16. Test results are then provided from DUTs on the wafer 14 back through the probe card 18 to the test head 8 for transmission back to the test system controller 4. Once testing is complete, the wafer is diced up to separate the DUTs.

FIG. 2 shows a cross sectional view of components of a typical probe card 18. The probe card 18 is configured to provide both electrical pathways and mechanical support for the spring probes 16 that will directly contact the wafer. The probe card electrical pathways are provided through a printed circuit board (PCB) 30, an interposer 32, and a space transformer 34. Test data from the test head 8 is provided through connectors 24 typically connected around the periphery of the PCB 30. The connectors 24 may be one of a number of different type connectors including pogo pin connectors, or flexible cable connectors. Channel transmission lines 40 distribute signals from the connectors 24 horizontally in the PCB 30 to contact pads on the PCB 30 to match the routing pitch of pads on the space transformer 34. The interposer 32 includes a substrate 42 with spring probe electrical contacts 44 disposed on both sides. The interposer 32 electrically connects individual pads on the PCB 30 to pads forming a land grid array (LGA) on the space transformer 34. Traces 46 in a substrate 45 of the space transformer 34 distribute or “space transform” connections from the LGA to spring probes 16 configured in an array.

Mechanical support for the electrical components is provided by a back plate 50, bracket (Probe Head Bracket) 52, frame (Probe Head Locating Frame) 54, leaf springs 56, and leveling pins 62. The back plate 50 is provided on one side of the PCB 30, while the bracket 52 is provided on the other side and attached by screws 59. The leaf springs 56 are attached by screws 58 to the bracket 52. The leaf springs 56 extend to movably hold the frame 54 within the interior walls of the bracket 52. The frame 54 then includes horizontal extensions 60 for supporting the space transformer 34 within its interior walls. The frame 54 surrounds the probe head and maintains a close tolerance to the bracket 52 such that lateral motion is limited.

Leveling pins 62 complete the mechanical support for the electrical elements and provide for leveling of the space transformer 34. The leveling pins 62 are adjusted so that brass spheres 66 provide a point contact with the space transformer 34. The spheres 66 contact outside the periphery of the LGA of the space transformer 34 to maintain isolation from electrical components. Leveling of the substrate is accomplished by precise adjustment of these spheres through the use of advancing screws, or leveling pins 62. The leveling pins 62 are screwed through supports 65 in the back plate 50 and PCB 30. Motion of the leveling pin screws 62 is opposed by leaf springs 56 so that spheres 66 are kept in contact with the space transformer 34. FIG. 3 shows an exploded assembly view of components of the probe card of FIG. 2 See, U.S. Pat. No. 6,509,751, issued Jan. 21, 2003, entitled “Planarizer for a Semiconductor Contactor,” and co-pending U.S. patent application Ser. No. 09/527,931, filed Mar. 17, 2000 entitled “Methods for Planarizing a Semiconductor Contactor” , incorporated herein by reference. FIG. 4 shows a perspective view of the opposing side of PCB 30 from FIG. 3, illustrating the arrangement of connectors 24 around its periphery.

In some cases, manufacturers testing DUTs on a wafer desire to determine results from only one DUT, or less than all the DUTs being tested. In one instance, monitoring test results from one DUT is desirable to verify accuracy of the test results performed by the test system controller on all DUTs being tested. In another instance, tests from only one DUT may be desired to indicate repairs needed to one or more of the DUTs, since taking time to receive and process results from all DUTs connected to a test system may be unnecessary and time consuming. Accordingly, it is desirable to provide a system for testing a number of DUTs while providing an optional interface for providing test results from one or a limited number of the DUTs.

### SUMMARY

In accordance with the present invention, monitoring of test signals is provided between the test system controller and one or more DUTs during testing. Such monitoring enables confirmation of test results from at least one DUT. Such monitoring further provides a number of features including—(1) ensuring that the test system controller is functioning properly, (2) enabling a test operator to verify operation more rapidly rather than waiting for a compilation of data from the test system controller, and (3) enabling a test operator to monitor a particular DUT quickly which is posing problems or so that modifications can be made on the particular DUT and confirmed before similar modifications are made to the remaining DUTs on a wafer.

Monitoring of test signals is provided by including a diagnostic interface connection on the PCB of the probe card. The diagnostic interface includes a connector that contacts the channel lines provided to one or more of the particular DUTs. The diagnostic interface connection to the PCB of the probe card allows signals to be brought out from a convenient position to connect to a user interface such as a personal computer. To prevent signal distortion in test signals on the channel lines due to long lines of the diagnostic interface, in one embodiment buffers are provided on the PCB as part of the interface connector connecting to the channels.

The signals from the interface connector in one embodiment are further provided to an adapter pod for processing so that the test results can be directly displayed to a system user. The adapter pod can include a digital signal processor (DSP) connected through an AMD converter for receiving analog current and voltages provided to and from a DUT. The DSP then functions to provide a displayable list of the test voltages and currents from particular inputs and outputs of the one or more DUTs being monitored. In another embodiment, the interface pod receives digital signals provided to and from the DUTs at the DSP that bypass the A/D converter, and the DSP functions to provide data indicating the accuracy of the test results based on the digital signals received.

In another embodiment, the adapter pod serves to distribute test signals to a plurality of output connectors without processing by a DSP. The adapter pod output connectors in one embodiment distribute the same signals to a number of different display devices. In another embodiment, the output connectors are connected to divide up the signal lines from the input interface connector. For example, one adapter pod output connector can carry only input signals to the DUT, while another can carry only output signals from the DUT, while yet another can carry the power supply line signals.

### BRIEF DESCRIPTION OF THE DRAWINGS

Further details of the present invention are explained with the help of the attached drawings in which:

FIG. 1 shows a block diagram of components of a conventional wafer test system;

FIG. 2 is a cross sectional view of a conventional probe card for the wafer test system of FIG. 1;

FIG. 3 is an exploded assembly view of components of the probe card of FIG. 2;

FIG. 4 is a perspective view of the PCB of FIG. 2 showing connectors for connecting to a test head;

FIG. 5 shows a perspective view of components of test system with a diagnostic interface according to the present invention;

FIG. 6 shows a block diagram of one embodiment of components making up the test system of FIG. 5; and

FIG. 7 shows a block diagram of another embodiment of components making up the test system of FIG. 5.

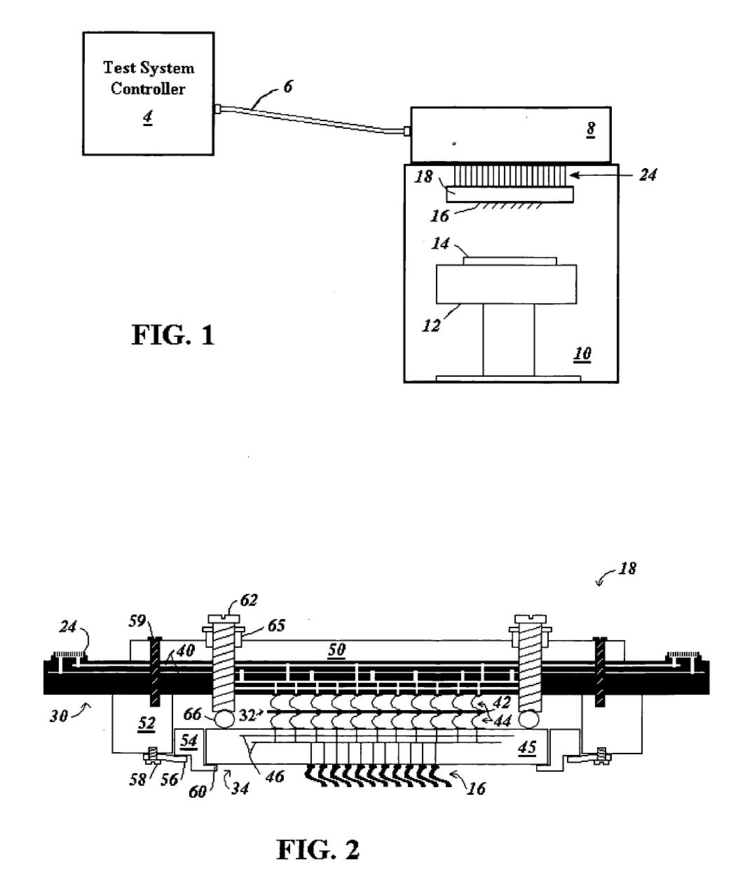

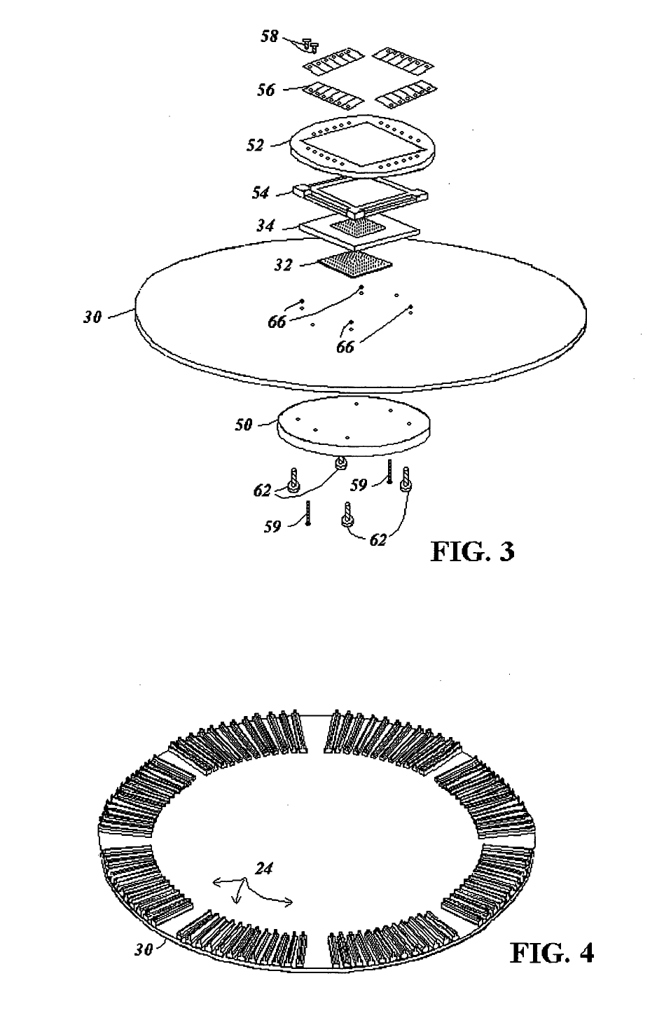

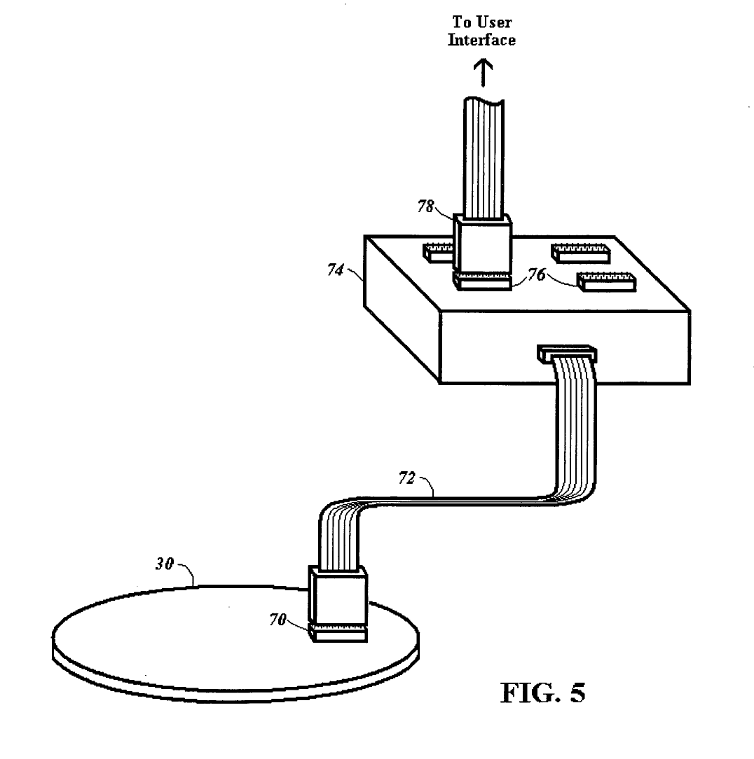

### DETAILED DESCRIPTION

FIG. 5 shows a perspective view of components of test system with a diagnostic interface according to the present invention. As shown, the diagnostic interface includes a connector 70 attached to the PCB 30 of a probe card. The test head connectors 24 adjacent to the connector 70 on the PCB 30 are not shown in FIG. 5. The diagnostic interface connector 70 includes connections to channel lines 40 in the PCB 30 that carry signals between a test system controller and probes for connecting to one or more DUTs. The components of the probe card apart from the diagnostic interface connector 70 to the PCB 30 remain the same, with reference to FIG. 2 including channel lines 40 of the PCB 30 linking through an interposer 32 and space transformer 34 to probes 16 for contacting to DUTs on a wafer.

The diagnostic interface connector 70 is preferably a fine pitch impedance controlled socket that may be a pogo pin type connector, a ZIF connector, or other vertical interface connector depending on design requirements. The diagnostic interface connector 70 is shown connected to a flexible ribbon cable type connector 72. Although shown as a flexible ribbon cable type connector, the connector 72 can be one of a number of connection types, such as soldered wires or another more rigid type connector. The connector 72 can connect directly to a user interface, such as a personal computer, or it can be connected to one or more user interfaces through an adapter pod 74, as shown in FIG. 5.

The adapter pod 74 can include different components, depending on the amount of processing of the test signals that is desired prior to providing test results to one or more user interfaces. In one embodiment the adapter pod 74 includes components that process the signals provided from the DUTs to provide test result data to a user interface device. The adapter pod 74 can further include components that distribute the signals received from the interface connector 70 to a plurality of connections 76, as shown, with or without the adapter pod 74 performing processing. The plurality of connections 76 can provide identical signals to multiple user interface devices, or can separate the signals into one or a number of categories such as DUT inputs, DUT outputs, and DUT power supply lines. Connections to a user interface device can be provided by the ribbon cable connector 78 shown in FIG. 5.

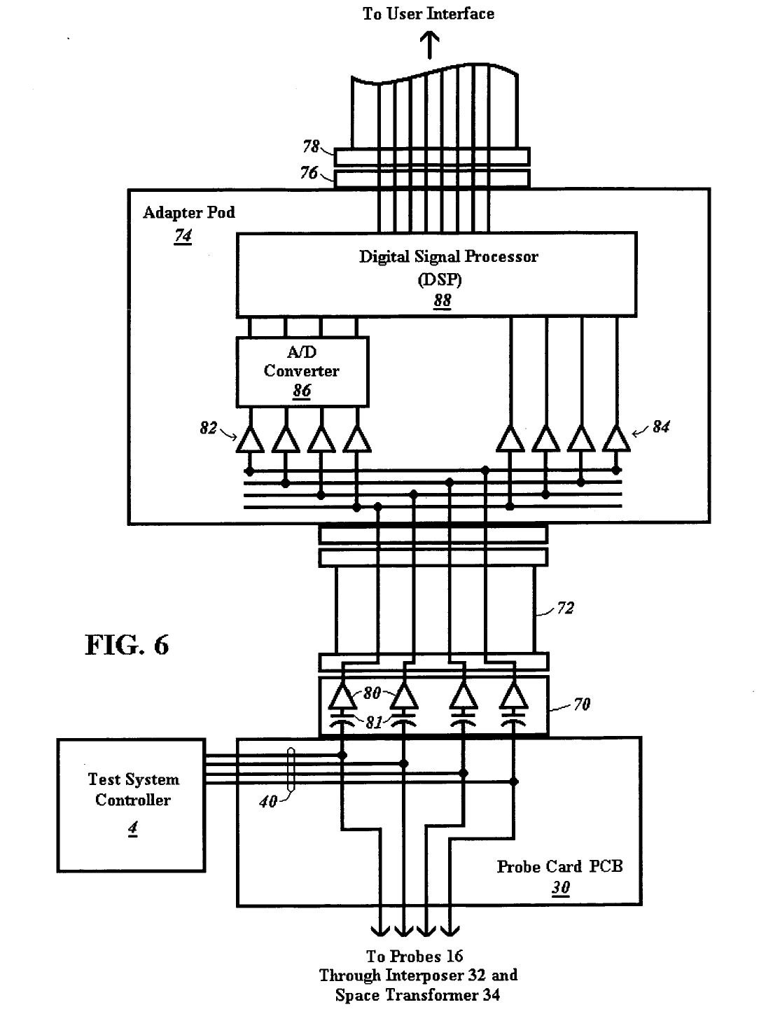

FIG. 6 shows a block diagram of one embodiment of components making up the test system of FIG. 5. The diagnostic interface connector 70 can include a direct connection to the channel lines 40 of the PCB. But, as shown in FIG. 6, buffers 80 can be included to limit distortion with signals on the channel lines 40. The buffers 80 in one embodiment are active devices attached to the probe card PCB 30 and powered by the test system controller 4 to provide a high impedance to the channel lines 40. The buffers 80 serve to provide an output accurately representing current and voltage on the channel line to drive components connected to the interface connector 70. The buffers 80 in one embodiment are high speed non-inverting digital signal line drivers. Either in addition to, or as an alternative to the buffers 80, decoupling capacitors 81 can be included in the diagnostic interface connector 70. Although the decoupling capacitors 81 will only provide limited compensation with long signal lines connected to the interface connector 70, the decoupling capacitors 81 can limit distortion of the test signals on the channels.

Although shown provided as part of the connector 70, in one embodiment, the buffers 80 and capacitor 81 can be provided in a buffer card that is attached to the PCB 30. The buffer card can be formed as a separate layer of the PCB 30, or attached to the PCB 30 as a separate daughter card by connectors on the PCB 30. The buffers 80 and capacitors 81 supported on the buffer card then connect the channel lines of the PCB 30 to the separate diagnostic interface connector 70.

The lines from the interface connector 70 in FIG. 6 run through the flexible connector cable 72 to the adapter pod 74. The adapter pod 74 is shown distributing signals through two separate sets of buffers 82 and 84 to provide for separate processing of analog signals and digital signals. Although provisions for processing both analog and digital signals are shown, only one type of connection is necessary if only one set of test results is required. The analog signals are provided through A/D converters 86 to a digital signal processor (DSP) 88, while digital signals are provided directly to the DSP 88 to process the test results.

The DSP 88 can be programmed to recognize the test being performed based on the signals received, or alternatively can have a connection (not shown) to the test system controller 4 to enable the DSP 88 to determine the type of test and to process the test results. As an alternative to the DSP 88, another type processor can be used with programming controlled by software stored in an attached memory device. Test signals measured by the DSP 88 may result from parametric tests where leakage current or voltage is measured, requiring the AID converter 86 and analog measurement analysis to process test results from buffers 82. The test signals measured may alternatively include a digital signal from a DUT output, requiring the digital signals provided from buffers 84 to enable the DSP 88 to process test results. Test results from the DSP 88 are provided through connectors 76 and 78 to a user interface device where either display of the results or further manipulation of the test results may be performed.

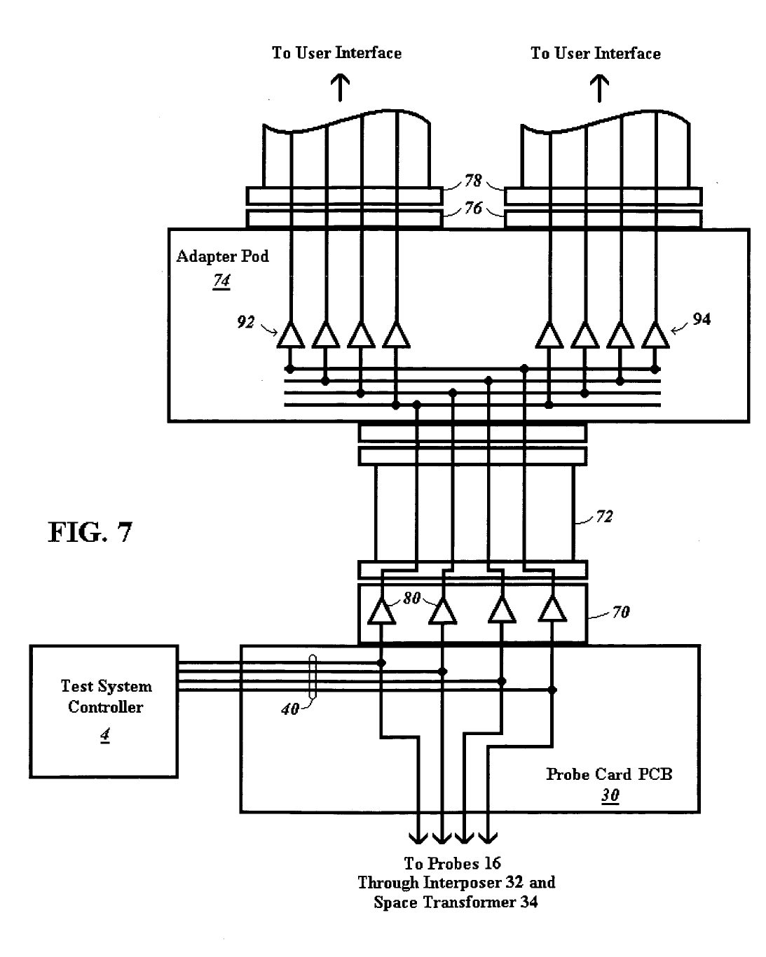

FIG. 7 shows a block diagram for an alternative embodiment of components making up the test system of FIG. 5 allowing for multiple outputs to be provided from the adapter pod 74. Like the buffers 82 and 84 of FIG. 7, the signals input to the adapter pod 74 are provided to two sets of buffers 92 and 94. The outputs of buffers 92 and 94, however, are then provided directly to separate connectors 76 and 78 as outputs of the adapter pod 74. Although distribution of input signals to two separate connectors 76 are shown, additional buffering can be included to distribute signals to more output connectors. Further, although all input signals to the adapter pod 74 are shown distributed equally to each output connector 76, as an alternative different input signals can be distributed to different outputs. In this manner output connectors 76 can separate the input signals into groups, such as inputs to the DUT, outputs from the DUT, and DUT power supply connections.

FIG. 7 is further modified by removing DSP processing performed in the adapter pod 74 in FIG. 6. Because processing of the test signals of a single DUT can be performed by a user interface as simple as a personal computer, software can be stored in the user interface to determine test results from the signals received. As with a DSP described in FIG. 6, a connection can be provided from the test system controller 4 to enable the user interface to determine the test being performed. Although FIG. 7 shows multiple output connections 76 provided without a processor, the output of a processor included in the adapter pod 74 of FIG. 6 can be distributed to multiple output connectors to provide test results to multiple test devices.

Although the present invention has been described above with particularity, this was merely to teach one of ordinary skill in the art how to make and use the invention. Many additional modifications will fall within the scope of the invention, as that scope is defined by the following claims.

1. a test system comprising:
a probe card configured to provide signals from a test system controller through channels to contacts for connecting to pads of devices under tests (DUTs); and
a diagnostic interface attached to the probe card, the diagnostic interface including electrical connections to at least some of the channels for connecting to at least one of the DUTs.

2. The test system of claim 1 further comprising:
buffers connecting the electrical connections of the diagnostic interface to the channels.

3. The test system of claim 1 further comprising:
compensation capacitors connected to each of the electrical connections of the diagnostic interface.

4. The test system of claim 1 further comprising:
an adapter pod having an input connected to a connector forming the diagnostic interface, and an output for connecting to a user interface, the adapter pod including a processor configured to process signals from the channels and provide data results for display by the user interface.

5. The test system of claim 4, wherein the adapter pod further comprises:
an A/D converter between at least some lines of the connector of the diagnostic interface and the processor.

6. The test system of claim 1 further comprising:
an adapter pod having an input connected a connector forming the diagnostic interface, and a plurality of outputs for distributing signals from the diagnostic interface to a plurality of additional interface connectors.

7. The test system of claim 6, wherein the plurality of additional interface connectors are connected to separate the lines from the diagnostic interface into different categories including at least two of DUT input lines, DUT output lines and power supply lines.

8. The test system of claim 1, wherein the probe card includes a PCB supporting the diagnostic interface as well as test head connectors for connecting the channels from the PCB to the test system controller.

9. The test system of claim 8 wherein the probe card further comprises:
a space transformer supporting spring probes that form the contacts for connecting to pads of the DUTs; and
an interposer connecting the channels of the PCB to electrical contacts attached to the spring probes of the space transformer.

10. The test system of claim 1, wherein the contacts comprise resilient spring probes.

11. A test system comprising:
a test system controller;
means for electrically contacting devices under test (DUTs);
channels connecting the test system controller to the means for electrically contacting the DUTs; and
means for connecting to at least a portion of the channels for providing test signals to a user interface.

12. The test system of claim 11,
wherein the means for electrically contacting DUTs comprises a probe card containing the channels and supporting contacts connected to the channels for contacting pads to the DUTs on a wafer, and
wherein the means for connecting to at least a portion of the channels comprises buffers having inputs connected to the portion of the channels and outputs configured for connecting to a user interface.

13. The test system of claim 12, wherein the contacts comprise resilient spring probes.

14. The test system of claim 11, further comprising:
means for processing test signals received from the means for connecting to at least a portion of the channels to provide test results to the user interface.

15. A method of testing devices under test (DUTs) on a wafer comprising:
providing a diagnostic interface in a wafer test system; and
monitoring test signals provided between a test system controller and at least one device under test (DUT) using the diagnostic interface.

16. The method of claim 15, further comprising:
buffering signals provided to the diagnostic interface from the wafer test system to minimize noise on signals in the wafer test system.

17. The method of claim 15, further comprising:
splitting of signals provided in the diagnostic interface to provide to multiple user interfaces.

18. The system of claim 1, further comprising a user interface for monitoring the at least one of the DUTs through the diagnostic interface.

19. The method of claim 15, wherein monitoring is performed through a user interface connected to the diagnostic interface.
